(19) United States
(12) Patent Application Publication
(10) Pub. No.: US 2022/0392909 A1
(43) Pub. Date: Dec. 8, 2022

(54) MEMORY DEVICE WITH STAGGERED ISOLATION REGIONS

(71) Applicant: GLOBALFOUNDRIES U.S. Inc., Malta, NY (US)

(72) Inventor: Shady Ahmed Abdelwahed Ahmed ELSHAFIE, Dresden (DE)

(21) Appl. No.: 17/339,071

(22) Filed: Jun. 4, 2021

(51) Int. Cl. H01L 27/11524; H01L 27/11519; H01L 29/06

(52) U.S. Cl. CPC H01L 27/11524; H01L 27/11519; H01L 29/0653

(57) ABSTRACT

The present disclosure relates to semiconductor structures and, more particularly, to a memory device with staggered isolation regions and methods of manufacture. The structure includes: a source line; a gate structure adjacent to the source line; and isolation structures on opposing sides of the source line. The isolation structures on a first side of the source line are laterally offset from the isolation structures on a second side of the source line.

### FIELD OF THE INVENTION

The present disclosure relates to semiconductor structures and, more particularly, to a memory device with staggered isolation regions and methods of manufacture.

### BACKGROUND

Flash memory is a non-volatile memory that can be electrically erased and reprogrammed. For example, flash memory may be erased, written, and read in blocks that are much smaller than the entire device. Flash memory packages can use die stacking with through-silicon vias and several dozen layers of cells (per die) to achieve very large capacities. Super Flash memory technology utilizes split-gate cell architecture to provide superior performance, data retention and reliability over conventional stacked gate flash memory.

Flash memory stores information in an array of memory cells made from floating-gate transistors. In single-level cell devices each cell stores only one bit of information; whereas, in multi-level cell devices, more than one bit can be stored per cell. The flash memory also includes embedded source lines.

Lithographic technologies limit the ability to make the source lines thinner. This being the case, lithographic boundaries prevent scaling down of dimensions of the source line and, hence, the memory device. Also, near the lithographic boundaries, image contrast is poor resulting in random patterned widths and unsystematic pinching of the source line. These issues increase resistance of the source line and lead to unwanted voltage drops. Also, these issues limit the density of the bit cells in the memory.

### SUMMARY

In an aspect of the disclosure, a structure comprises: a source line; a gate structure adjacent to the source line; and isolation structures on opposing sides of the source line, the isolation structures on a first side of the source line being laterally offset from the isolation structures on a second side of the source line.

In an aspect of the disclosure, a structure comprises: a source line comprising semiconductor material; a floating gate structure on at least a first side of the source line; a first set of shallow trench isolation structures within the semiconductor material and which extend from the first side of the source line; and a second set of shallow trench isolation structures within the semiconductor material and which extend from a second, opposing side of the source line, the second set of shallow trench isolation structures being staggered from the first set of shallow trench isolation structures along a length of the source line.

In an aspect of the disclosure, a method comprises: forming a source line; forming a gate structure adjacent to the source line; and forming isolation structures on opposing sides of the source line, the isolation structures on a first side of the source line being formed laterally offset from the isolation structures on a second side of the source line.

### BRIEF DESCRIPTION OF THE DRAWINGS

The present disclosure is described in the detailed description which follows, in reference to the noted plurality of drawings by way of non-limiting examples of exemplary embodiments of the present disclosure.

FIG. 1A shows a top view of a memory cell in accordance with aspects of the present disclosure.

FIG. 1B shows a cross-sectional view of the memory cell of FIG. 1A, along line A-A.

FIG. 1C shows a cross-sectional view of the memory cell of FIG. 1A, along line B-B.

FIG. 1D shows a cross-sectional view of the memory cell of FIG. 1A, along line C-C.

FIG. 2 shows a top view of a memory device with a plurality of bit cells in accordance with aspects of the present disclosure.

FIGS. 3A and 3B show cross-sectional views of fabrication processes of the memory cell shown in FIGS. 1A-1D, in accordance with aspects of the present disclosure.

FIGS. 4A and 4B show a comparison of aerial intensity and pinch-off between a known memory device (FIG. 4A) and the memory device with staggered isolation structures in accordance with the present disclosure (FIG. 4B).

FIG. 5 shows a scanning electron microscope (SEM) image of a known memory device with source line pinch-off issues.

### DETAILED DESCRIPTION

The present disclosure relates to semiconductor structures and, more particularly, to a memory device with staggered isolation regions and methods of manufacture. More specifically, the present disclosure comprises staggered or laterally shifted shallow trench isolation lines along a length of a source line in a bit cell. Advantageously, the staggered isolation regions allow for higher yield of the memory device, a larger shallow trench isolation lithography process window and higher bit cell density. As to the latter advantage, by implementing the staggered isolation regions, it is possible to achieve approximately 4% or more cell area reduction.

In embodiments, the memory device includes extending the optical lithography boundaries for scaling down embedded flash memory. For example, a super flash memory structure comprises staggered (e.g., laterally shifted) shallow trench isolation fingers or lines in the source line region of the device. The use of the staggered shallow trench isolation fingers or lines will result in a mis-alignment of the shallow trench isolation features on opposing sides of the source line which contribute to an increase in the spacing between isolation regions on opposing sides of the source line (e.g., space end to space end (SE-to-SE) spacing). This allows scaling down of the width of the source line (SL) by approximately 44%. In addition, the use of the shallow trench isolation fingers or lines with a lateral shift will allow for an increase of resist image contrast, and reduce and even eliminate pinching at the source line.

The memory device with staggered isolation regions of the present disclosure can be manufactured in a number of ways using a number of different tools. In general, though, the methodologies and tools are used to form structures with dimensions in the micrometer and nanometer scale. The methodologies, i.e., technologies, employed to manufacture the memory device of the present disclosure have been adopted from integrated circuit (IC) technology. For example, the structures are built on wafers and are realized in films of material patterned by photolithographic processes on the top of a wafer. In particular, the fabrication of the memory device uses three basic building blocks: (i) deposition of thin films of material on a substrate, (ii) applying a patterned mask on top of the films by photolithographic imaging, and (iii) etching the films selectively to the mask.

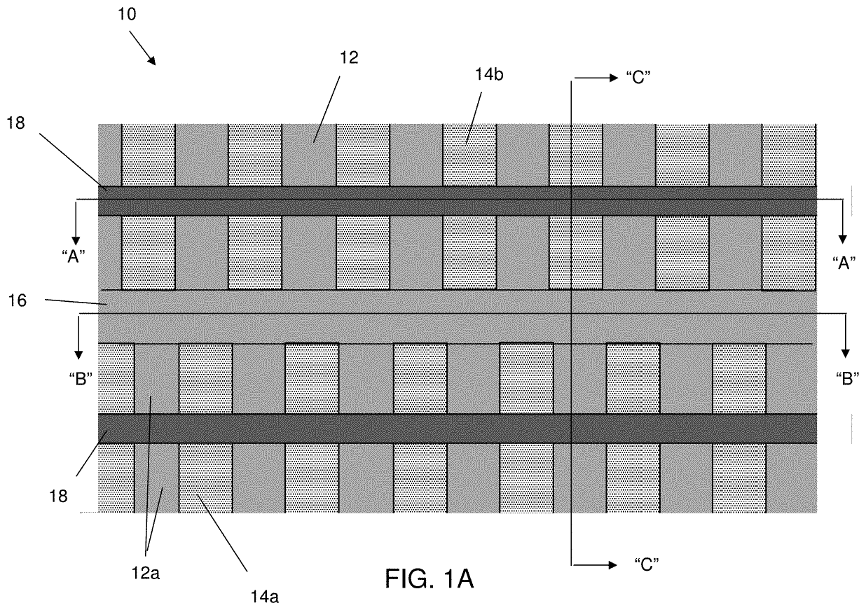

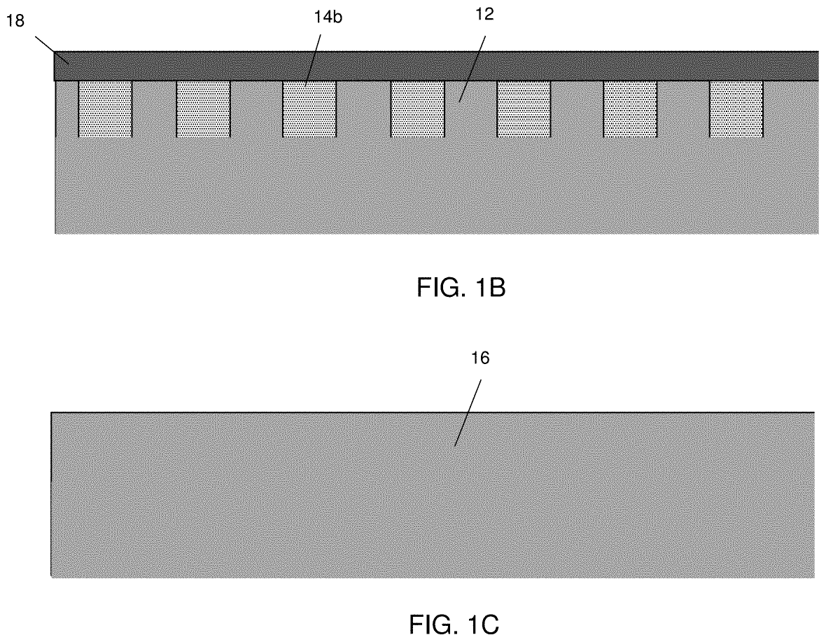

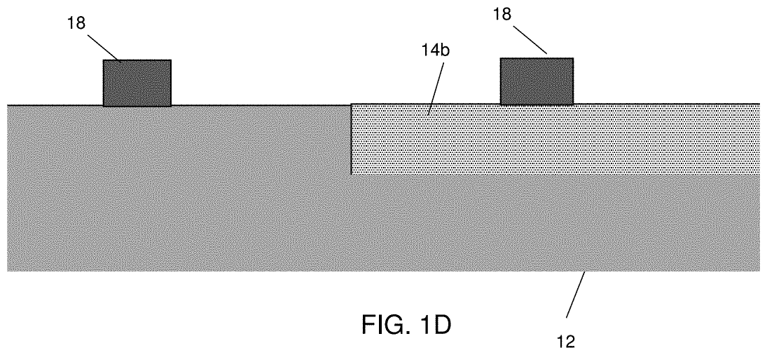

FIG. 1A shows a top view of a memory cell 10 in accordance with aspects of the present disclosure and FIG. 1B-1D show different cross-sectional views of the memory cell 10 of FIG. 1A. For example, FIG. 1B shows a cross-sectional view of the memory cell 10 of FIG. 1A, along line A-A; FIG. 1C shows a cross-sectional view of the memory cell 10 of FIG. 1A, along line B-B; and FIG. 1D shows a cross-sectional view of the memory cell 10 of FIG. 1A, along line C-C.

Referring to FIGS. 1A-1D, the memory cell 10 includes a semiconductor substrate 12. The semiconductor substrate 12 can be a bulk substrate or a semiconductor on insulator (SOI) substrate. In embodiments, the semiconductor substrate 12 may be composed of any suitable material including, but not limited to, Si, SiGe, SiGeC, SiC, GaAs, InAs, InP, and other III/V or II/VI compound semiconductors. In further embodiments, the semiconductor substrate 12 may comprise any suitable crystallographic orientation (e.g., a (100), (110), (111), or (001) crystallographic orientation). The semiconductor substrate 12 is preferably planar.

In the SOI implementation, the semiconductor substrate 12 would be on an insulator layer which, in turn, is over a semiconductor wafer. The insulator layer comprises any suitable material including silicon oxide, sapphire, other suitable insulating materials, and/or combinations thereof. An exemplary insulator layer may be a buried oxide layer (BOX). The insulator layer may be formed by any suitable process, such as separation by implantation of oxygen (SIMOX), oxidation, deposition, and/or other suitable process.

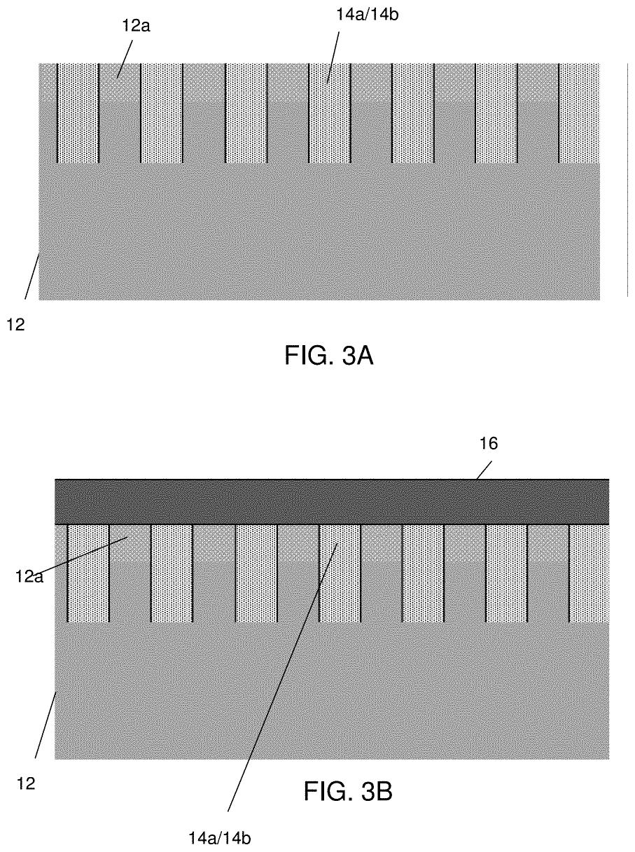

As further shown in FIGS. 1A-1D, multiple shallow trench isolation structures 14a, 14b are formed on opposing sides of a source line 16. In embodiments, the source line 16 comprises the semiconductor substrate 12. As shown, the shallow trench isolation structures 14a on a first side of the source line 16 are offset (e.g., laterally shifted) or staggered from the shallow trench isolation structures 14b on a second or opposing side of the source line 16. In preferred embodiments, the shallow trench isolation structures 14a may be laterally shifted from the shallow trench isolation structures 14b by up to ½ pitch along the length of the source line 16; although other offset pitches are contemplated herein. For example, in certain technologies, the offset between the lateral shift of the shallow trench isolation structures 14a, 14b can be about 63 nm. The shallow trench isolation structures 14a, 14b can be formed orthogonal to the source line 16 by conventional lithography, etching and deposition processes as described in more detail with respect to FIG. 3A.

By having a lateral shift between the shallow trench isolation structures 14a, 14b, on opposing sides of the source line 16, it is now possible to increase SE-to-SE spacing, while also scaling down the width of the source line 16. This is due to the fact that shallow trench isolation structures 14a, 14b are further apart from one another compared to known devices in which the shallow trench isolation structures 14a, 14b are aligned with one another. Moreover, as the shallow trench isolation structures 14a, 14b are further apart, the pinching effect of the source line 16 can be reduced and even eliminated. As should be understood by those of ordinary skill in the art, a pinch-off of the source line 16 may result in an increase in resistance of the source line 16 and, hence, an unwanted voltage drop and/or a complete malfunction of a plurality of gate structures as a result of a physical cut (e.g., pinching) in the source line 16 which cuts the way to accessing those gate structures. However, these issues are now avoided by implementing the structures described herein. Also, it is now possible to encounter larger process variations (e.g., larger shallow trench isolation lithography process windows) without concern for pinch-off of the source line 16.

FIGS. 1A-1D further show gate structures 18 extending over the shallow trench isolation structures 14a, 14b, on opposing sides of the source line 16. In embodiments, the gate structures 18 may be floating gate structures used to read, erase and write to the memory device. As described in more detail with respect to FIG. 3B, the gate structures 18 can be polysilicon or metal gate structures.

Moreover, source and drain regions 12a can be provided in the semiconductor substrate 12 on opposing sides of the gate structures 18. As is known in the art, the source and drain regions 12a can be formed with different fabrication processes. For example, the source and drain regions 12a can be formed by a doping or ion implantation process, the latter of which is described in more detail with respect to FIG. 3A. The source and drain regions 12a can also be raised epitaxy source and drain regions formed by selectively growing a semiconductor material on the semiconductor substrate 12 implanted with a p-type or an n-type impurity.

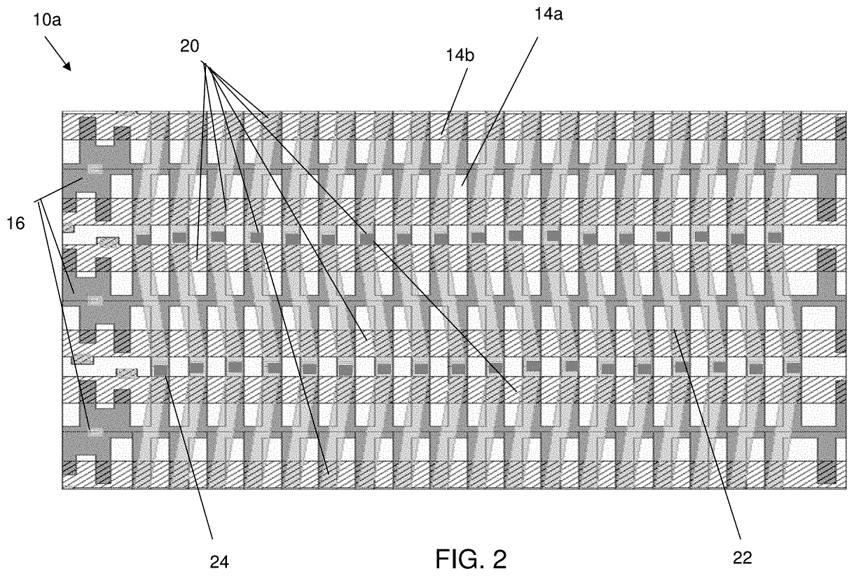

FIG. 2 shows a memory device with a plurality of bit cells in accordance with aspects of the present disclosure. In this representation, the memory device 10a includes a plurality of gate structures 20 which provide access to the plurality of gate structures 18, e.g., floating gates structures, shown in FIG. 1D for example. In embodiments, the plurality of gate structures 20 may be wordlines. The memory device 10a also includes a plurality of source lines 16 and the shallow trench isolation structures 14a, 14b provided in a staggered configuration as already described herein.

A plurality of conductive lines 22, e.g., metal lines, are provided below the plurality of gate structures 20 and above the plurality of gate structures 18. In embodiments, the metal lines 22 are wavy or bent due to the staggered configuration of the shallow trench isolation structures 14a, 14b; that is, the wavy metal lines 22 substantially align with the shallow trench isolation structures 14a, 14b. Contacts 24 are provided from the plurality of metal lines 22 to the semiconductor substrate, e.g., source line 16, the plurality of gate structures 20 and the plurality gate structures 18, e.g., floating gates structures.

FIGS. 3A and 3B show cross-sectional views of fabrication processes of the memory cell 10 shown in FIGS. 1A-1D. As shown in FIG. 3A, for example, the shallow trench isolation structures 14a, 14b are formed in the semiconductor substrate 12 using conventional lithography, etching and deposition processes. For example, a resist formed over the semiconductor substrate 12 is exposed to energy (light) to form a staggered or laterally shifted pattern (opening) as shown, e.g., in FIG. 1A. An etching process with a selective chemistry, e.g., reactive ion etching (RIE), will be used to form one or more trenches in the semiconductor substrate 12 through the openings of the resist. Following the resist removal by a conventional oxygen ashing process or other known stripants, insulator material (e.g., SiO₂) can be deposited by any conventional deposition processes, e.g., chemical vapor deposition (CVD) processes. Any residual insulator material on the surface of the semiconductor substrate 12 can be removed by conventional chemical mechanical polishing (CMP) processes thereby providing a planar surface of the semiconductor substrate 12 and the shallow trench isolation structures 14a, 14b.

Still referring to FIG. 3A, the source and drain regions 12a can be formed in the semiconductor substrate 12 by introducing a dopant using, for example, ion implantation processes. As is known in the art, the ion implantation processes will introduce a concentration of a dopant in the semiconductor substrate 12. In embodiments, a patterned implantation mask may be used to define selected areas exposed for the implantations. The implantation mask may include a layer of a light-sensitive material, such as an organic photoresist, applied by a spin coating process, pre-baked, exposed to light projected through a photomask, baked after exposure, and developed with a chemical developer. The implantation mask has a thickness and stopping power sufficient to block masked areas against receiving a dose of the implanted ions. The implantation mask is stripped after the implantation process by use of conventional stripants known to those of skill in the art, e.g., oxygen ashing, etc.

FIG. 3B shows the fabrication processes of the gate structures 18. Although not critical to the understanding of the present disclosure, the gate structures 18 can be fabricated using conventional CMOS processes as either metal gate structures or polysilicon gate structures. In the standard CMOS processing, a gate dielectric and polysilicon (or workfunction metals) and, if necessary, a capping material are formed, e.g., deposited, onto the semiconductor substrate 12, followed by a patterning process. An insulator material such as nitride or oxide can be deposited on the patterned materials, followed by an anisotropic etching process to form sidewalls. After gate formation, additional processing can be performed for other features, e.g., extension implants, source/drain and gate contacts (as required), etc., as is well known in the art such that no further explanation is required.

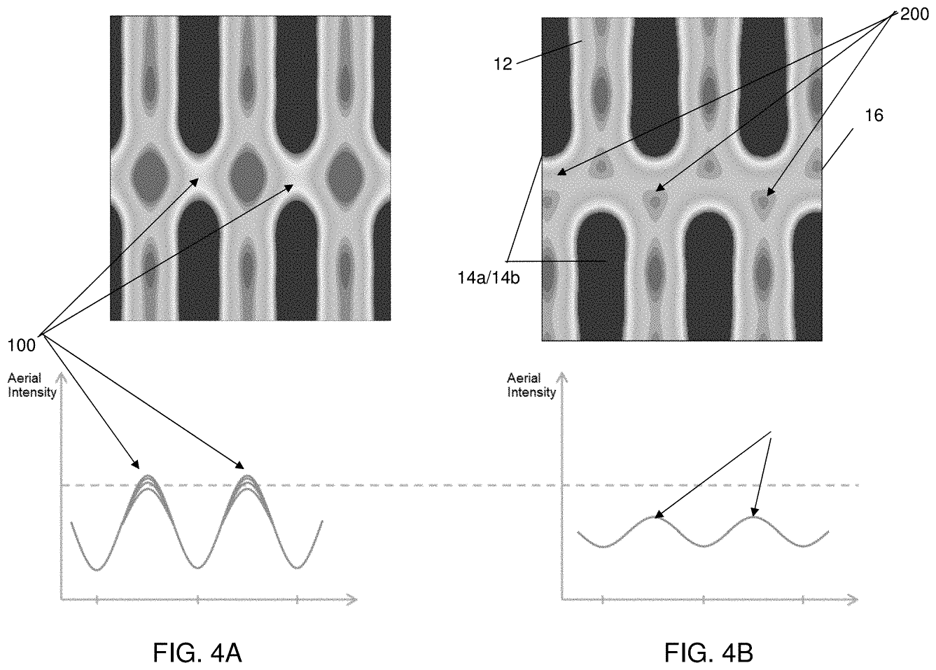

FIGS. 4A and 4B show a comparison of aerial intensity of a known memory device (FIG. 4A) and the memory device with staggered isolation structures in accordance with the present disclosure (FIG. 4B). Specifically, the memory device of FIG. 4A shows a breakdown (e.g., pinch-off) of the source line at location 100 between the aligned shallow trench isolation structures; whereas, in FIG. 4B, the source line at location 200 does not exhibit any breakdown (e.g., pinch-off) between the laterally shifted shallow trench isolation structures 14a, 14b.

In the memory device of FIG. 4A, the pinch-off is due to the fact that the aligned shallow trench isolation structures are too close together and, due to process variations of the lithographic process, the resist threshold is exceeded as shown in the graph at location 100, e.g., the anal intensity exceeds the resist threshold value as represented by the dashed line. In comparison, the laterally shifted shallow trench isolation structures 14a, 14b shown in FIG. 4B provides a larger SE-to-SE spacing on the source line 16. In this case, even with process variations of the lithographic process, it is possible to be further away from the lithographic limitations thereby avoiding or eliminating pinch-off of the source line 16. This being the case, it is now possible to reduce the width of the source line 16 which, in turn, allows for a total reduction in space making it possible to increase the bit cell density while also increasing yield (as the source line will not pinch-off).

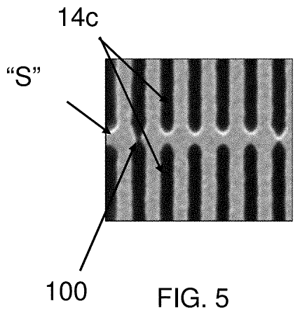

FIG. 5 shows a scanning electron microscope (SEM) image of a known memory device. As shown in this image, the source line S is pinched-off at location 100 between the aligned shallow trench isolation structures 14c. This pinch-off is a complete break of the source line S resulting in a higher resistance and unwanted voltage drops, compared to that of the memory device of the present disclosure. Moreover, a line-thinning can result in higher resistance and voltage drop, where pinch-off is a worst case condition of a thinned line.

The memory device can be utilized in system on chip (SoC) technology. It should be understood by those of skill in the art that SoC is an integrated circuit (also known as a “chip”) that integrates all components of an electronic system on a single chip or substrate. As the components are integrated on a single substrate, SoCs consume much less power and take up much less area than multi-chip designs with equivalent functionality. Because of this, SoCs are becoming the dominant force in the mobile computing (such as in Smartphones) and edge computing markets. SoC is also commonly used in embedded systems and the Internet of Things.

The method(s) as described above is used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed:

1. A structure comprising:
a source line;
a gate structure adjacent to the source line; and
isolation structures on opposing sides of the source line, the isolation structures on a first side of the source line being laterally offset from the isolation structures on a second side of the source line.

2. The structure of claim 1, wherein the gate structure comprises a floating gate structure.

3. The structure of claim 1, wherein the isolation structures comprise shallow trench isolation structures within semiconductor material.

4. The structure of claim 3, wherein the source line comprises the semiconductor material.

5. The structure of claim 1, wherein the source line comprises bulk semiconductor material.

6. The structure of claim 1, wherein the source line comprises semiconductor on insulator material.

7. The structure of claim 1, wherein the isolation structures and the source line are planar and the isolation structures are offset along a length of the source line.

8. The structure of claim 1, wherein the isolation structures on the first side are laterally shifted along a length of the source line from the isolation structures on the second side by up to ½ pitch.

9. The structure of claim 1, further comprising wavy conductive lines substantially aligned with the isolation structures.

10. The structure of claim 9, further comprising wordlines contacting the wavy conductive lines, and the wavy conductive lines contacting to at least the gate structure.

11. A structure comprising:
a source line comprising semiconductor material;
a floating gate structure on at least a first side of the source line;
a first set of shallow trench isolation structures within the semiconductor material and which extend from the first side of the source line; and
a second set of shallow trench isolation structures within the semiconductor material and which extend from a second, opposing side of the source line, the second set of shallow trench isolation structures being staggered from the first set of shallow trench isolation structures along a length of the source line.

12. The structure of claim 11, wherein the floating gate structure comprises polysilicon material.

13. The structure of claim 11, wherein the floating gate structure comprises workfunction metal.

14. The structure of claim 11, wherein the semiconductor material comprises bulk semiconductor material.

15. The structure of claim 11, wherein the semiconductor material comprises semiconductor on insulator material.

16. The structure of claim 11, wherein the first set of shallow trench isolation structures are laterally shifted from the second set of shallow trench isolation structures by up to ½ pitch.

17. The structure of claim 11, further comprising wavy conductive lines which connect to the source line and the floating gate structure.

18. The structure of claim 17, further comprising a plurality of gate structures connecting to the wavy conductive lines.

19. The structure of claim 17, wherein the wavy conductive lines substantially align with the first set of shallow trench isolation structures and second set of shallow trench isolation structures.

20. A method comprising:
forming a source line;
forming a gate structure adjacent to the source line; and
forming isolation structures on opposing sides of the source line, the isolation structures on a first side of the source line being formed laterally offset from the isolation structures on a second side of the source line.
